(19) United States
(12) Patent Application Publication
(10) Pub. No.: US 2026/0282989 A1
(43) Pub. Date: Sep. 17, 2026

(54) Semiconductor Device and Method of Making Using Dual-Laser Compression Bonding

(71) Applicant: JCET STATS ChipPAC Korea Limited, Incheon (KR)

(72) Inventors: Yeojun Yun, Incheon (KR); SeungHyun Lee, Incheon (KR); HeeSoo Lee, Incheon (KR)

(73) Assignee: JCET STATS ChipPAC Korea Limited, Incheon (KR)

(21) Appl. No.: 19/078,098

(22) Filed: Mar. 12, 2025

(51) Int. Cl. H01L 23/00

(52) U.S. Cl. CPC H10W 72/072; H10W 72/0711; H10W 72/016; H10W 72/07125; H10W 72/07141; H10W 72/07232; H10W 72/07235; H10W 72/07236

(57) ABSTRACT

A semiconductor device manufacturing method has a first semiconductor die. A second semiconductor die is stacked over the first semiconductor die with a solder bump disposed between the first semiconductor die and second semiconductor die to form a semiconductor die stack. The semiconductor die stack is disposed between a first laser and a second laser. The solder bump is reflowed by emitting a first laser beam from the first laser onto the first semiconductor die and emitting a second laser beam from the second laser onto the second semiconductor die. The semiconductor die stack is disposed in a vacuum chamber while reflowing the solder bump.

### FIELD OF THE INVENTION

The present invention relates in general to semiconductor devices and, more particularly, to a semiconductor device and method of making by dual-laser compression bonding.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. Stacking multiple die interconnected by through-silicon via (TSV) technology is important to reduce electrical parasitic components related to electrical interconnect between die. TSV technology improves electrical performance because it provides shorter electrical wiring distance compared to bond wires or flip-chip technology. However, die stacking in the prior art relies on laser-assisted bonding (LAB), which currently limits multi-stack bonding. Therefore, a need exists for improved compression bonding for die stacks.

### BRIEF DESCRIPTION OF THE DRAWINGS

FIGS. 1a-1g illustrate a semiconductor wafer with a plurality of semiconductor die and through-silicon vias;

FIGS. 2a-2k illustrate forming a die stack by dual-laser compression bonding;

FIG. 3 illustrates a manufacturing line for dual-laser compression bonding;

FIGS. 4a-4c illustrate forming a semiconductor package with the die stack; and

FIGS. 5a and 5b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

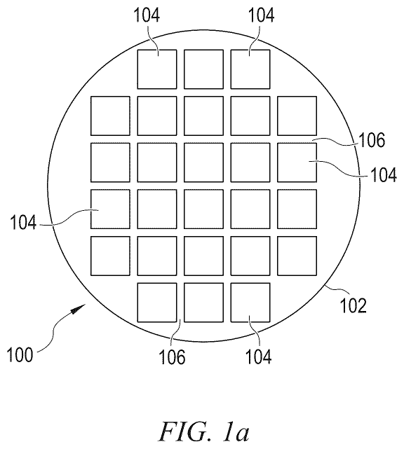

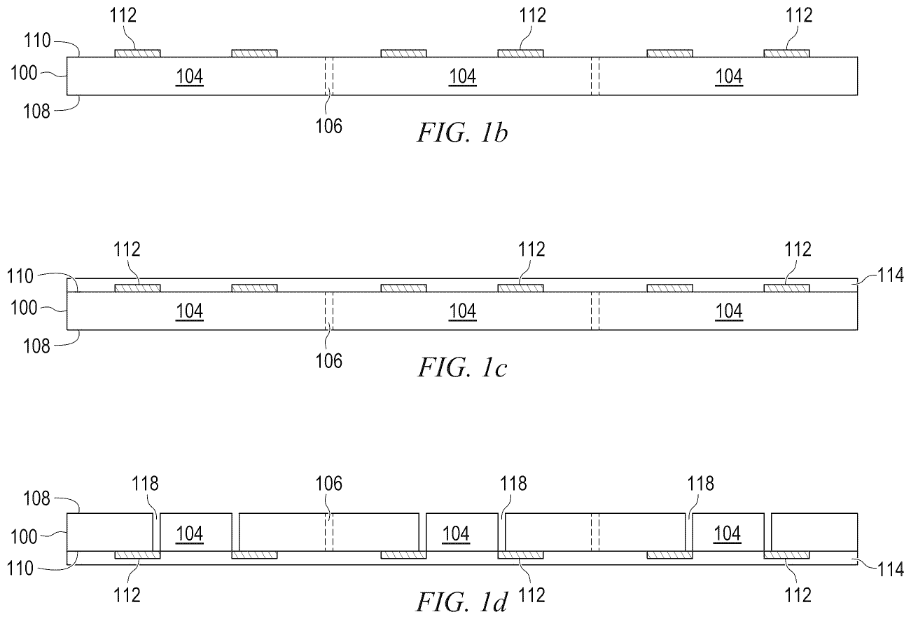

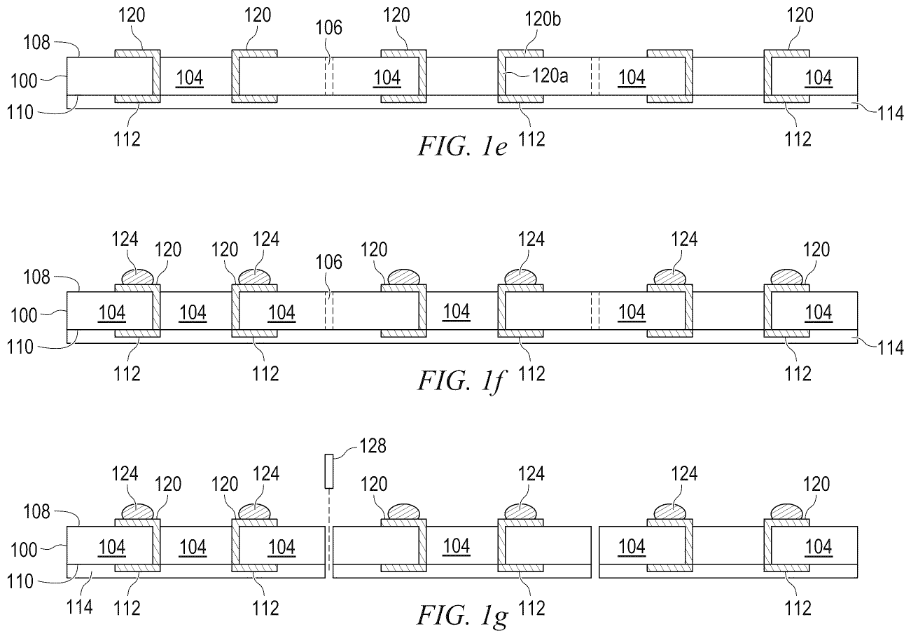

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processors (DSP), application specific integrated circuits (ASIC), memory, power devices, or other signal processing circuits. Semiconductor die 104 may also contain IPDs, such as inductors, capacitors, and resistors, for RF signal processing. Surfaces 108 and 110 are essentially interchangeable, and active circuit elements can be formed in or on either or both of surfaces 108 and 110.

An electrically conductive layer 112 is formed over active surface 110 using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110. Conductive layer 112 can be patterned to include conductive traces and contact pads as desired to implement the intended functionality of semiconductor die 104.

In FIG. 1c, an optional insulating layer or nonconductive film (NCF) 114 is formed over conductive layer 112. NCF 114 is a layer of silica and epoxy in one embodiment. In other embodiments, NCF 114 can be flux or epoxy flux to aid in subsequent solder bump reflow. The epoxy of NCF 114 can remain uncured or only partially cured until a later step when compression bonding occurs. In other embodiments, NCF 114 is an insulating layer containing one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI), benzocyclobutene (BCB), polybenzoxazoles (PBO), and other material having similar insulating and structural properties. NCF 114 can be formed using PVD, CVD, printing, lamination, spin coating, spray coating, sintering, or thermal oxidation. Any insulating, passivation, or dielectric layer mentioned above or below can be formed using any of the materials or methods described for insulating layer 114.

In FIG. 1d, wafer 100 is flipped and vias 118 are formed through the wafer. Vias 118 are holes formed perpendicularly through the thickness of wafer 100 from surface 108 to surface 110. Vias 118 are formed by mechanical drilling, chemical etching, deep reactive-ion etching (DRIE), or another suitable process. Vias 118 are formed completely through wafer 100 to expose conductive layer 112 from the top of wafer 100. Conductive layer 112 includes contact pads exposed by vias 118. Vias 118 can be formed near a middle of the contact pads or at an edge as shown.

In FIG. 1e, conductive layer 120 is formed over back surface 108 and into vias 118 as described above for conductive layer 112. Conductive vias 120a extend vertically through wafer 100 while conductive layer 120b extends horizontally across surface 108. In one embodiment, conductive material for conductive layer 120 is deposited to fill vias 118 and completely cover surface 108, and then the material on surface 108 is patterned to form contact pads and conductive traces as desired to implement the intended electric functionality of semiconductor die 104. In other embodiments, conductive vias 120a are formed in vias 118 first, and then contact pads 120b are formed on surface 108 in a separate manufacturing step. Conductive layer 120 is electrically connected to conductive layer 112 through vias 118.

In FIG. 1f, an electrically conductive bump material is deposited over conductive layer 120 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 120 using a suitable attachment or bonding process. In one embodiment, the bump material is reflowed by heating the material above its melting point to form bumps 124. Bump 124 can also be compression bonded or thermocompression bonded to conductive layer 120. In one embodiment, bump 124 is formed over an under-bump metallization (UBM) having a wetting layer, barrier layer, and adhesion layer. Bumps 124 are optional and can be formed on conductive layer 112 instead of or in addition to conductive layer 120.

In FIG. 1g, semiconductor wafer 100 is singulated through saw street 106 using a saw blade or laser cutting tool 128 into individual semiconductor die 104. The individual semiconductor die 104 can be inspected and electrically tested for identification of known good die or unit after singulation.

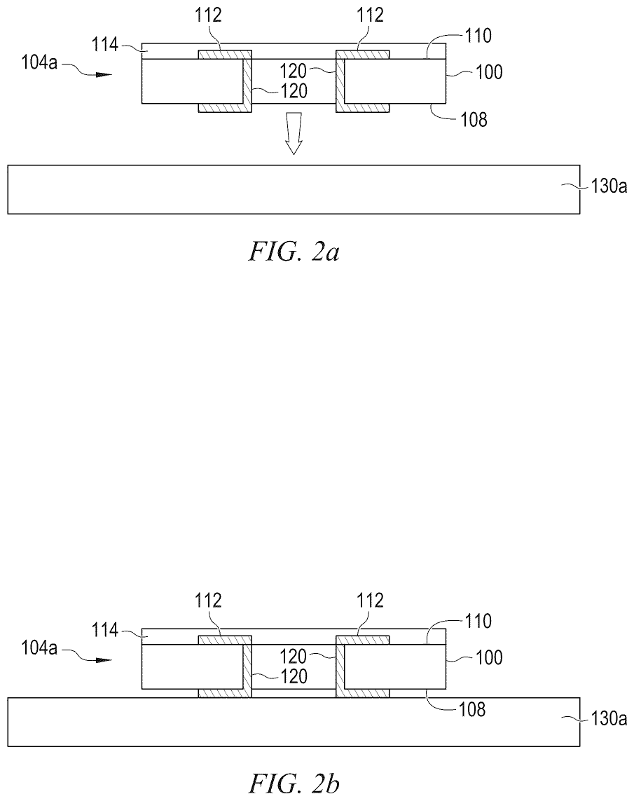

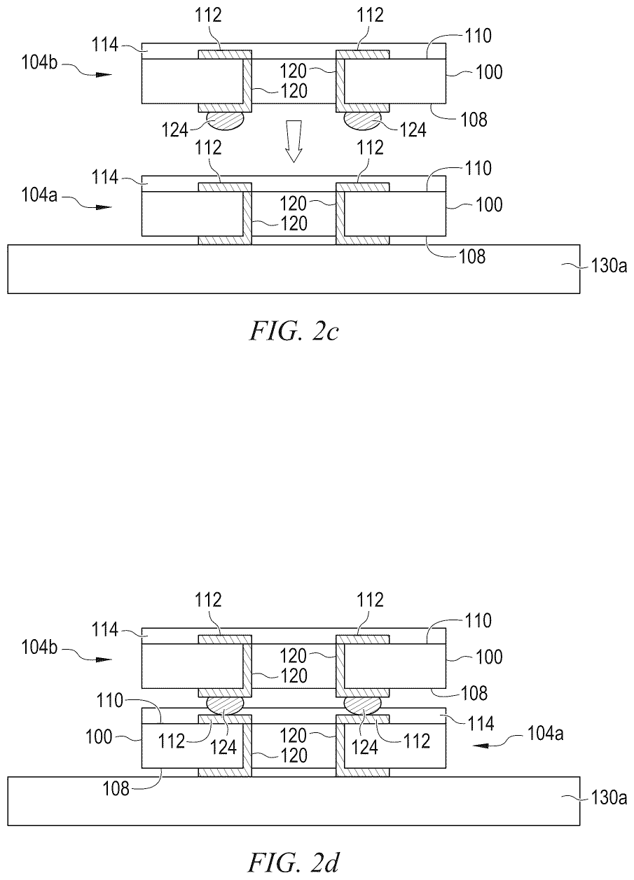

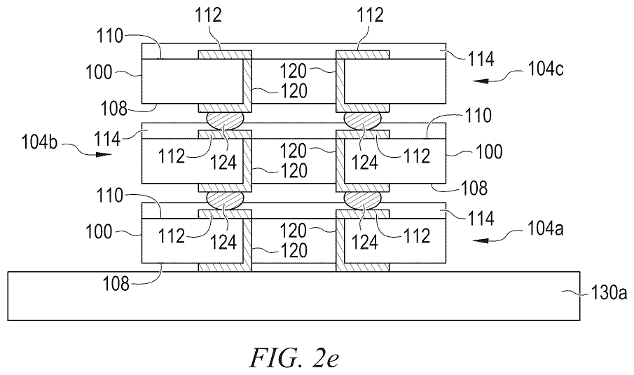

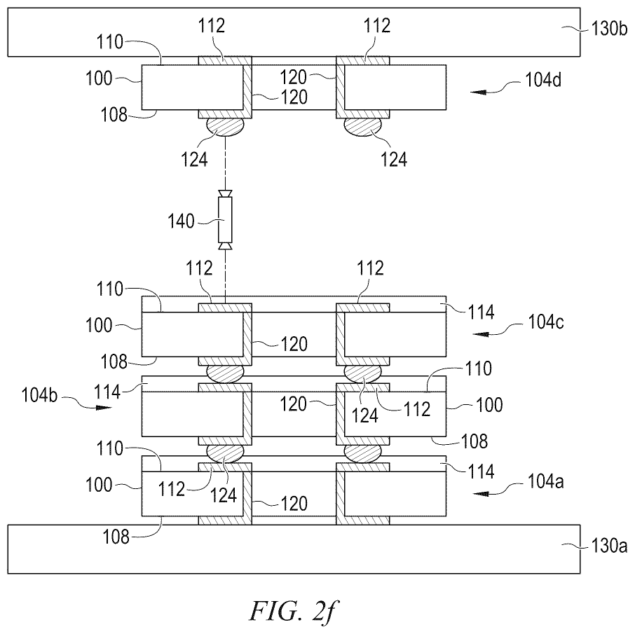

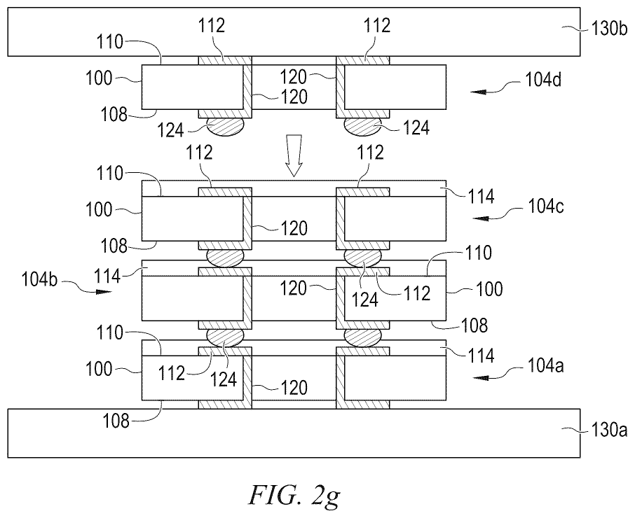

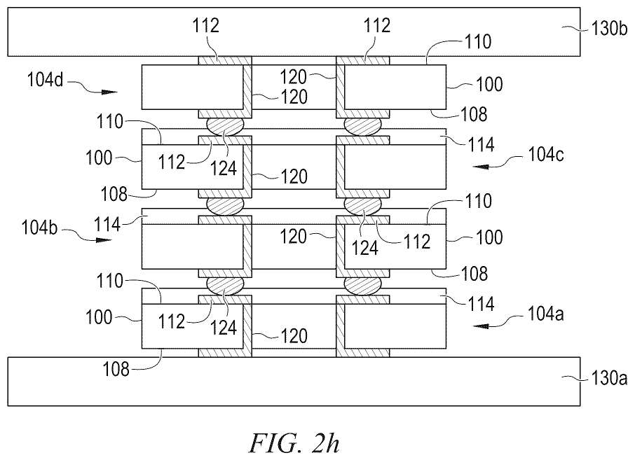

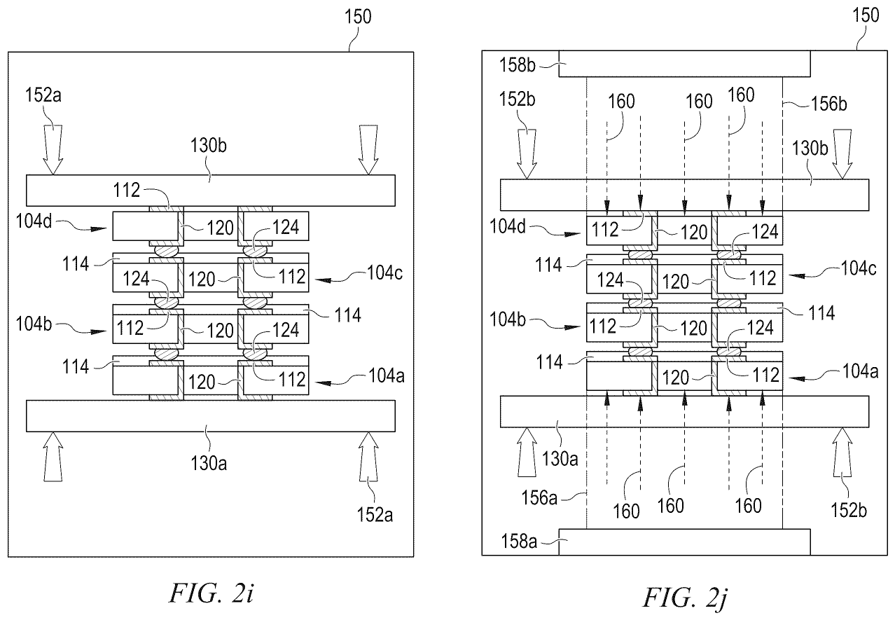

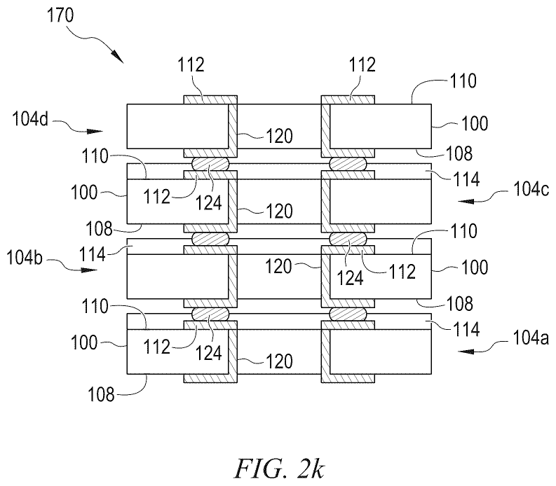

FIGS. 2a-2k illustrate forming a die stack with semiconductor die 104 using dual-laser compression bonding. In FIG. 2a, a first semiconductor die 104a is disposed over a quartz block 130a. Quartz block 130a is translucent to allow laser light to travel through the quartz block and impinge on semiconductor die 104a. Other types of laser transparent or translucent materials are used for quartz block 130a in other embodiments.

Semiconductor die 104a is picked and placed over quartz block 130a and then placed onto the quartz block in FIG. 2b. An optional adhesive layer is used to keep semiconductor die 104a in place on quartz block 130a. Semiconductor die 104a is placed with the optional NCF 114 oriented up away from quartz block 103a. Semiconductor die 104a is provided without solder bumps 124 because the bottom semiconductor die of the stack being formed does not need bumps in the present embodiment. The stack will be packaged in a way that does not rely on the stack being pre-bumped. Bumps 124 are only used to interconnect the stacked semiconductor die 104 in this embodiment, and not for subsequent interconnect of the stack as a whole. Semiconductor die 104a optionally has bumps 124 in other embodiments.

In FIG. 2c, a second semiconductor die 104b is picked and placed over semiconductor die 104a with bumps 124 oriented down toward semiconductor die 104a. In FIG. 2d, semiconductor die 104b is placed down on semiconductor die 104a with bumps 124 of die 104b resting on conductive layer 112 of semiconductor die 104a. The pick and place machine can apply enough downward force on semiconductor die 104a such that bumps 124 of semiconductor die 104b are pressed through NCF 114 of semiconductor die 104a. Typically, the amount of force required to penetrate NCF 114 is not significant enough to misshape solder bumps 124. NCF remains uncured or only partially cured at this stage, so bumps 124 can pass through the NCF relatively easily. In another embodiment, bumps 124 remain resting on NCF 114 at this stage, and only penetrate through the NCF during later compression bonding.

Additional semiconductor die 104 can be stacked to any suitable total number of semiconductor die, including two or more semiconductor die. FIG. 2e shows a third semiconductor die 104c stacked on semiconductor die 104b as described above for semiconductor die 104b on semiconductor die 104a. Bumps 124 of semiconductor die 104c rest on either NCF 114 or conductive layer 112 of semiconductor die 104b.

In FIG. 2f, a fourth semiconductor die 104d is mounted onto a quartz block 130b using an adhesive layer between the semiconductor die and quartz block to stick the semiconductor die to the quartz block. Semiconductor die 104d is picked and placed onto quartz block 130b as shown in FIGS. 2a and 2b for semiconductor die 104a on quartz block 104a. In the case of semiconductor die 104d, bumps 124 are formed and oriented away from quartz block 130b. Semiconductor die 104d is prepared without NCF 114 because the NCF is primarily used to protect bumps 124, but as the top semiconductor die 104 in the stack no bumps will be mounted to conductive layer 120 of semiconductor die 124d. In other embodiments, semiconductor die 104d has NCF 114 formed so that every semiconductor die 104 can be prepared in the same process.

Quartz block 130b with semiconductor die 104d attached is disposed over the stacked semiconductor die 104a-104c in FIG. 2f. Bumps 124 of semiconductor die 104d are aligned to contact pads of semiconductor die 124c using an alignment camera 140. Alignment camera 140 is positioned to see the inner surfaces between quartz blocks 130a and 130b to allow alignment to be confirmed. Once aligned, quartz block 130b is moved down toward the stack of semiconductor die 104a-104c in FIG. 2g. In FIG. 2h, quartz block 130b is placed down such that semiconductor die 104d rests on semiconductor die 104c. Semiconductor die 104a-104d are stacked between quartz blocks 130a and 130b.

Compression bonding begins in FIG. 2i with a pre-bonding step. The stack of semiconductor die 104 is placed in a vacuum chamber 150. Vacuum chamber 150 is evacuated of air during compression bonding. The vacuum process reduces unintended oxidation of the copper metal, which oxidizes easily at high temperatures. Vacuum chamber 150 improves device reliability by reducing copper oxidization.

During pre-bonding, compression 152a is provided to press quartz blocks 130a and 130b toward each other. Compression 152a is applied only from the top against an underlying support in one embodiment. Compression 152a is applied with a total force of between 20-50 newtons (N) for between one second and five seconds. During pre-bonding, quartz blocks 130a and 130b are maintained at a temperature of between 100° C. and 130° C. using a heater in vacuum chamber 150, which is sufficient to create a temporary bonding of solder bumps 124 between semiconductor die 104a-104d.

Laser-compression bonding (LCB) occurs in FIG. 2j. The stack of semiconductor die 104a-104d remains between quartz blocks 130a and 130b within vacuum chamber 150. The compression 152a from pre-bonding is increased to compression 152b for LCB. Compression 152 b is a bonding pressure of between 50-100 N applied for between five and ten seconds. Compression 152b applies a force on quartz blocks 130a and 130b toward each other to compress the stack of semiconductor die 104a-104d. In some embodiment, LCB as shown in FIG. 2j is performed without the pre-bonding compression 152a of FIG. 2i.

In addition, bonding occurs by laser beams 156a and 156b being emitted from lasers 158a and 158b, respectively. Lasers 158a and 158b are devices that emit light through a process of optical amplification based on the stimulated emission of electromagnetic radiation. Laser 158a is disposed under quartz block 130a to emit laser beam 156a up through quartz block 130a to impinge on semiconductor die 104a. Laser 158b is disposed over quartz block 130b to emit laser beam 156b down through quartz block 130b to impinge on semiconductor die 104d. In one embodiment, lasers 158 emit beams 156 onto semiconductor die 104 for between 0.5 and 2.0 seconds, and the power output of lasers 158 is between 1,000 and 8,000 Watts. Laser beams 156 increase the temperature of semiconductor die 104 and quartz blocks 130 to between 230-300° C.

Individual photons 160 travel through quartz blocks 130a and 130b to hit semiconductor die 104. The energy of photons 160 is absorbed by semiconductor die 104 and converted to thermal energy. The thermal energy spreads between all four semiconductor die 104 to reflow bumps 124. Bumps 124 reflow onto the opposing conductive layer 112 to physically and electrically connect the stacked semiconductor die 104 to each other. In some embodiments, the same thermal energy also fully cures NCF 114.

Performing LCB with two separate lasers, one over semiconductor die 104 and one below the semiconductor die, promotes a relatively uniform application of thermal energy throughout the stack of semiconductor die. LCB occurs quicker than with a single laser because each laser only has to dissipate thermal energy halfway through the stack of semiconductor die 104, whereas a single laser would have to dissipate thermal energy completely through the stack. The shortened heating time provided by using two separate and opposing lasers reduces warpage.

FIG. 2k shows the stack 170 of semiconductor die 104a-104d after LCB. Stack 170 is removed from vacuum chamber 150 and quartz blocks 130. Performing LCB with two lasers 158 on opposite sides of stack 170 has improved the quality of solder joints of bumps 124. End devices are more reliable.

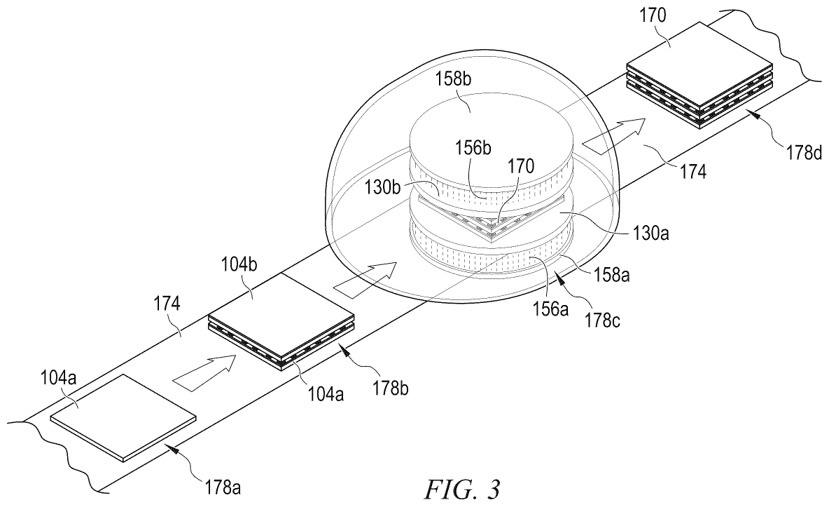

FIG. 3 shows a manufacturing line for stack 170. Processing occurs on a belt or track 174 that moves semiconductor die 104 through processing locations 178a-178d. Semiconductor die 104a is initially disposed at processing location 178a. Additional die 104b-104d can be stacked at processing location 178a, or semiconductor die 104a is moved to processing location 178b for stacking. Processing location 178c is within vacuum chamber 150.

Die stack 170 is moved into vacuum chamber 150 after being stacked at location 178a or 178b. LCB occurs in 178c including optional pre-bonding compression. In some embodiments, vacuum chamber 150 is large enough to allow one or more, up to even hundreds or thousands, of semiconductor die stacks 170 to be laser-compression bonded at one time. Track 174 includes an opening under quartz block 130a to allow laser beam 156a to go through the track to impinge on die stack 170. After LCB, track 174 moves stack 170 to processing location 178e for unloading. Unloading can occur by an unloader or a pick-and-place machine that removes stack 170 from track 174 and puts the stack into a JEDEC tray, tape-and-reel, or other suitable storage.

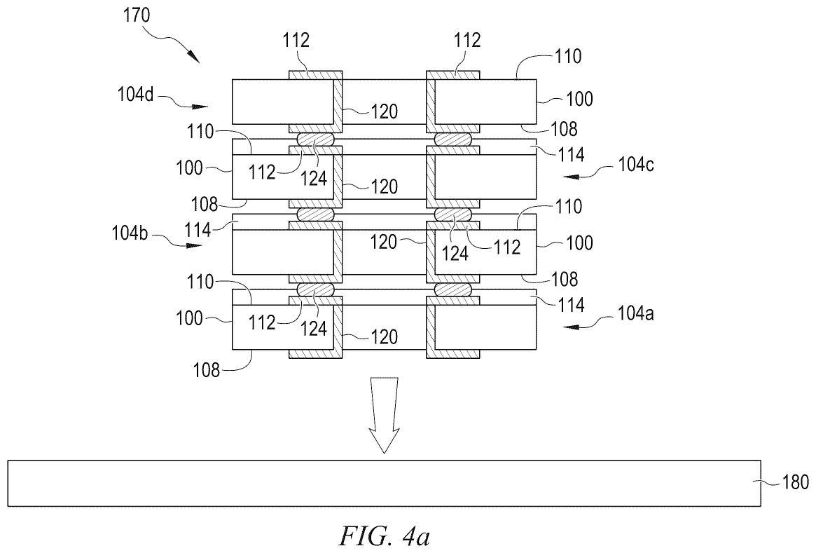

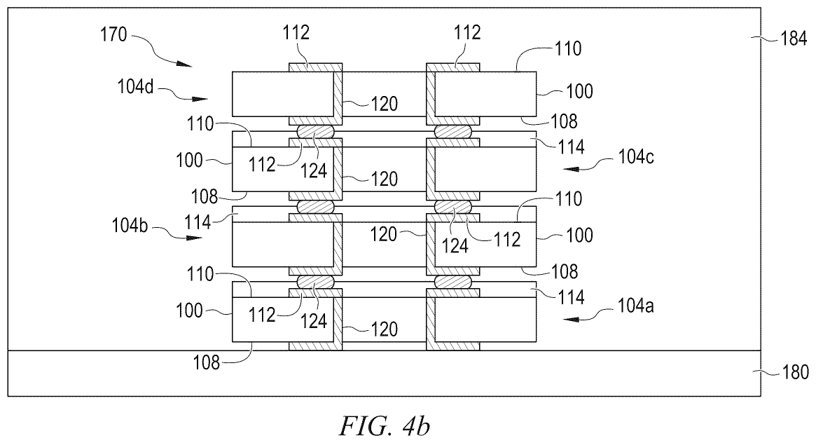

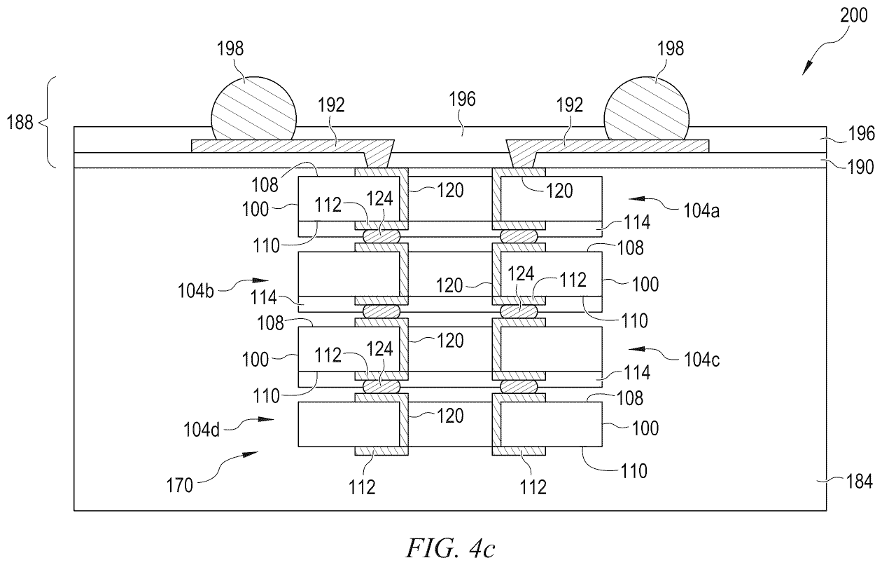

FIGS. 4a-4c illustrate the formation of a semiconductor package with stack 170. While one specific embodiment is shown, stack 170 can be included in any type of semiconductor package. In FIG. 4a, stack 170 is picked and placed onto a carrier 180 containing sacrificial base material such as silicon, polymer, beryllium oxide, glass, or other suitable low-cost, rigid material for structural support. An interface layer or double-sided tape is formed or disposed over carrier 180 as a temporary bonding film, thermal release layer, or UV release layer. To simplify illustration, the package being formed includes a single stack 170 and no other components. In other embodiments, much more complicated packages can be formed with multiple semiconductor die, additional discrete active or passive components, or any other desired electrical components. While carrier 180 is illustrated as large enough for manufacturing only a single device, a typical carrier can handle hundreds or thousands of devices at once, which are singulated from each other after or during the manufacturing process.

In FIG. 4b, encapsulant or molding compound 184 is deposited over and around semiconductor die 104 using a paste printing, compressive molding, transfer molding, liquid encapsulant molding, vacuum lamination, spin coating, or other suitable applicator. Encapsulant 184 can be liquid or granular polymer composite material, such as epoxy resin, epoxy acrylate, or another suitable polymer, with or without a suitable filler. Encapsulant 184 is non-conductive, provides structural support, and environmentally protects the semiconductor device from external elements and contaminants. In some embodiments, encapsulant 184 fills gaps left between semiconductor die 104. In other embodiments, NCF 114 completely fills the space between semiconductor die 104 and blocks encapsulant 184 from flowing between the semiconductor die.

In FIG. 4c, carrier 180 is removed to expose semiconductor die 104a, and a build-up interconnect structure 188 is formed over stack 170 and encapsulant 184. Build-up interconnect structure 188 is so-called because the interconnect structure is formed by building up conductive and insulating layers on top of a substrate, e.g., a panel of multiple stacks 170 embedded in encapsulant 184. Insulating layer 190 is formed on encapsulant 184 using the methods and materials described above for NCF 114. Openings are formed through insulating layer 190 to expose contact pads of conductive layer 120 of semiconductor die 104a.

A conductive layer 192 is formed over insulating layer 190 and into the openings in insulating layer 190 to physically contact and electrically connect to conductive layer 120. Conductive layer 192 is patterned using a mask, photolithography, chemical etching, laser ablation, jet printing, or another suitable method to form a redistribution layer (RDL) fanning out from the contact pads of conductive layer 120. In other embodiments, conductive layer 192 forms a fan-in interconnect structure. The individual conductive traces of conductive layer 192 have one end at a contact pad of conductive layer 120 and have contact pads or capture pads formed at their opposite ends.

Another insulating layer 196 is formed over conductive layer 192 as described for insulating layer 190. Openings are formed through insulating layer 196 to expose contact pads of conductive layer 192. Any number of additional insulating and conductive layers can be interleaved over conductive layer 192 and insulating layer 196 to add RDL layers and allow more complicated signal routing. Only a single RDL layer is illustrated to simplify illustration of the eWLB concept. Solder bumps 198 are formed on contact pads of conductive layer 192 in openings of insulating layer 196, as described above for bumps 124, to complete a semiconductor package 200 with a stack 170. In some embodiments, a panel of the packages 200 shown in FIG. 4c are formed as a panel connected to each other by encapsulant 184 and then singulated after bumps 198 are formed.

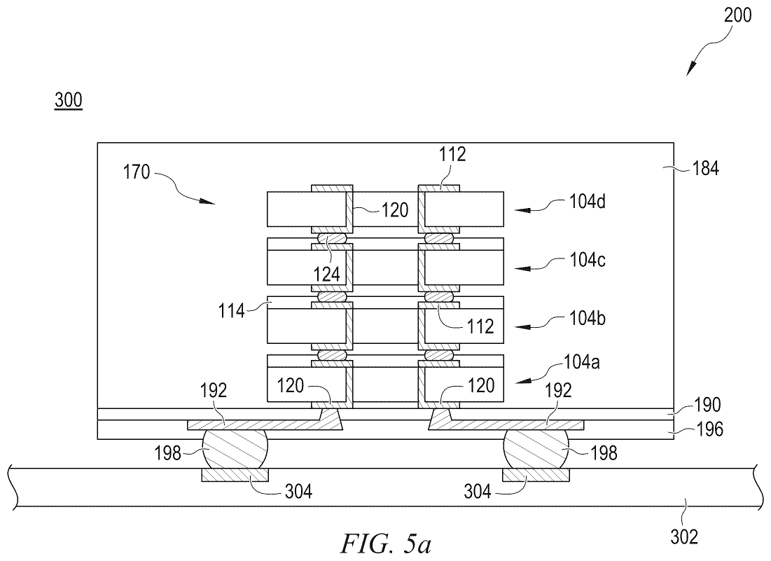

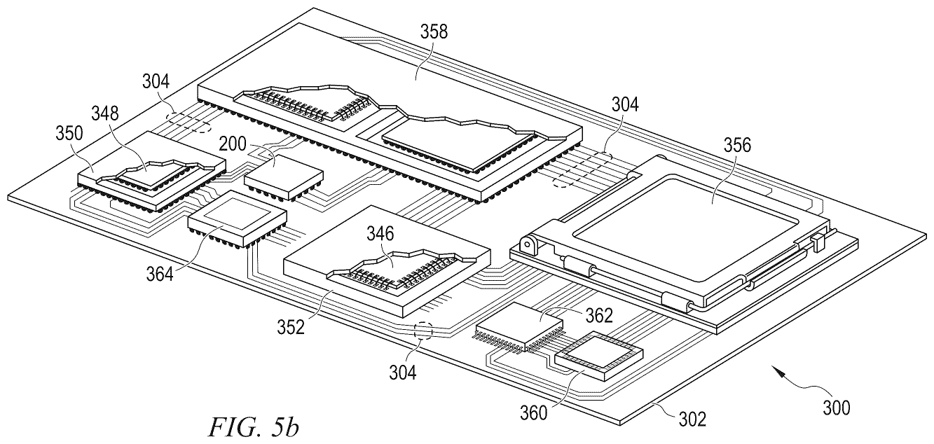

FIGS. 5a and 5b illustrate integrating the above-described semiconductor packages, e.g., semiconductor package 200, into a larger electronic device 300. FIG. 5a illustrates a partial cross-section of package 200 mounted onto a printed circuit board (PCB) or other substrate 302 as part of electronic device 300. Solder bumps 198 are reflowed onto conductive layer 304 of PCB 302 to physically attach and electrically connect semiconductor package 200 to the PCB. In other embodiments, thermocompression or another suitable attachment and connection methods are used. In some embodiments, an adhesive or underfill layer is used between semiconductor package 200 and PCB 302. Semiconductor die 104a-104d are electrically coupled to conductive layer 304 through build-up interconnect structure 188. Semiconductor die 104b-104c are electrically coupled to build-up interconnect structure 188 by through-silicon vias of conductive layer 120.

FIG. 5b illustrates electronic device 300 having a chip carrier substrate or PCB 302 with a plurality of semiconductor packages disposed on a surface of PCB 302, including semiconductor package 200. Electronic device 300 can have one type of semiconductor package, or multiple types of semiconductor packages, depending on the application. Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first semiconductor die;
stacking a second semiconductor die over the first semiconductor die with a solder bump disposed between the first semiconductor die and second semiconductor die to form a semiconductor die stack;
disposing the semiconductor die stack between a first laser and a second laser; and
reflowing the solder bump by,
emitting a first laser beam from the first laser onto the first semiconductor die, and
emitting a second laser beam from the second laser onto the second semiconductor die.

2. The method of claim 1, further including disposing the semiconductor die stack in a vacuum chamber while reflowing the solder bump.

3. The method of claim 1, further including:
disposing the first semiconductor die on a first quartz block; and
disposing the second semiconductor die on a second quartz block.

4. The method of claim 1, further including applying a compression to the semiconductor die stack while reflowing the solder bump.

5. The method of claim 4, further including:
applying the compression at a first magnitude during a first time period prior to reflowing the solder bump; and
increasing the magnitude of the compression after the first time period and prior to reflowing the solder bump.

6. The method of claim 1, further including disposing a non-conductive film between the first semiconductor die and second semiconductor die.

7. A method of making a semiconductor device, comprising:
providing a first semiconductor die;
stacking a second semiconductor die over the first semiconductor die with a solder bump disposed between the first semiconductor die and second semiconductor die to form a semiconductor die stack;
emitting a first laser beam from a first laser onto the first semiconductor die; and
emitting a second laser beam from a second laser onto the second semiconductor die.

8. The method of claim 7, further including disposing the semiconductor die stack in a vacuum chamber while emitting the first laser beam and second laser beam.

9. The method of claim 7, further including:
disposing the first semiconductor die on a first quartz block; and
disposing the second semiconductor die on a second quartz block.

10. The method of claim 7, further including applying a compression to the semiconductor die stack while emitting the first laser beam and second laser beam.

11. The method of claim 10, further including:
applying the compression at a first magnitude during a first time period prior to emitting the first laser beam and second laser beam; and
increasing the magnitude of the compression after the first time period and prior to emitting the first laser beam and second laser beam.

12. The method of claim 7, further including disposing a non-conductive film between the first semiconductor die and second semiconductor die.

13. The method of claim 7, further including stacking a third semiconductor die between the first semiconductor die and second semiconductor die.

14. A method of making a semiconductor device, comprising:
providing a first semiconductor die;
stacking a second semiconductor die over the first semiconductor die;
emitting a first laser beam from a first laser onto the first semiconductor die; and
emitting a second laser beam from a second laser onto the second semiconductor die.

15. The method of claim 14, further including disposing the semiconductor die stack in a vacuum chamber while emitting the first laser beam and second laser beam.

16. The method of claim 14, further including:
disposing the first semiconductor die on a first quartz block; and
disposing the second semiconductor die on a second quartz block.

17. The method of claim 14, further including applying a compression to the semiconductor die stack while emitting the first laser beam and second laser beam.

18. The method of claim 17, further including:
applying the compression at a first magnitude during a first time period prior to emitting the first laser beam and second laser beam; and
increasing the magnitude of the compression after the first time period and prior to emitting the first laser beam and second laser beam.

19. The method of claim 14, further including disposing a non-conductive film between the first semiconductor die and second semiconductor die.

20. The method of claim 14, further including stacking a third semiconductor die between the first semiconductor die and second semiconductor die.

21. A semiconductor manufacturing device, comprising:
a semiconductor die stack;
a first laser disposed over the semiconductor die stack; and
a second laser disposed over the semiconductor die stack opposite the first laser.

22. The semiconductor manufacturing device of claim 21, further including:
a first quartz plate; and
a second quartz plate, wherein the semiconductor die stack is disposed between the first quartz plate and second quartz plate.

23. The semiconductor manufacturing device of claim 21, further including a vacuum chamber, wherein the semiconductor die stack is disposed in the vacuum chamber.

24. The semiconductor manufacturing device of claim 21, wherein the semiconductor die stack includes:
a first semiconductor die;
a second semiconductor die; and
a first solder bump disposed between the first semiconductor die and second semiconductor die.

25. The semiconductor manufacturing device of claim 24, wherein the semiconductor die stack further includes:
a third semiconductor die disposed between the first semiconductor die and second semiconductor die; and
a second solder bump disposed between the second semiconductor die and third semiconductor die, wherein the first solder bump is disposed between the first semiconductor die and third semiconductor die.
